(19) United States
(12) Patent Application Publication
(10) Pub. No.: US 2005/0139994 A1
(43) Pub. Date: Jun. 30, 2005

(54) Semiconductor package

(75) Inventors: Hung-Ta Hsu, Kaohsiung (TW); Tzu-Bin Lin, Kaohsiung City (TW); Ya-Ling Huang, Kaohsiung City (TW)

Correspondence Address: BIRCH STEWART KOLASCH & BIRCH, PO BOX 747, FALLS CHURCH, VA, 22040-0747, US

(73) Assignee: Advanced Semiconductor Engineering Inc.

(21) Appl. No.: 11/023,353

(22) Filed: Dec. 29, 2004

(30) Foreign Application Priority Data
Dec. 31, 2003 (TW) 092137810

(51) Int. Cl. H01L 23/34; H01L 21/48

(52) U.S. Cl. 257/706; 257/712; 438/125; 257/778; 438/108

(57) ABSTRACT

A semiconductor package includes a die attached to a substrate. Multitudes of conductive structures are conductively connected the die and the substrate. One molding compound encapsulates the die, and thermal interface material is on the molding compound. Next, a heat sink is on the thermal interface material. The mold compound material performs a coefficient of thermal expansion smaller than the heat sink so as to prevent the die or substrate from the damages of internal stresses.

### BACKGROUND OF THE INVENTION

1. Field of the Invention

The present invention generally relates to a semiconductor package and more particularly to a semiconductor package with a heat sink.

2. Description of the Prior Art

Following the development of integrated circuit technology, the packing requirement is more and more strict for the IC (integrated circuit), because the packaging technology is directly related to the function of the electronic products. The conventional packaging methods include DIP (Dual In-line Package), QFP (Quad Flat Package), and PFP (Plastic Flat Package). When the frequency of IC exceeds 100 MHz, the conventional packaging method generates a phenomenon called “Cross-Talk”. Furthermore, when the number of pins is larger than 208, the packaging becomes more difficult in the conventional packaging technology. In addition to the QFP technology, the BGA (ball grid array package) technology is the most popular packaging technology if the chip has many pins, such as graphic chips and chip module. Thus, in the present, the BGA technology is the best choice for the chip with a high density, and high performance, and multitudes of pins such as CPU (central processing unit) and south/north bridges chip on/in the motherboard.

On the other hand, the BGA packaging technology can be classified into five types: PBGA (Plastic BGA) substrate, CBGA (Ceramic BGA) substrate, FCBGA (Flip chip BGA) substrate, TBGA (Tape BGA) substrate, and CDPBGA (Cavity Down PBGA) substrate. In the conventional, the IC packaging process is packaged from a single IC, which needs a leadframe or substrate, and also include some processes such as the die attach, bonding, molding, or trim and form processes, such that the chip size of the packaged IC is greater than the chip after the IC is packaged. Furthermore, package may provide a die with heat dissipation through thermal conductivity and convection. Thus, one type with heat sink, i.e. heat sink ball grid array (HSBGA), is designed for the requirement.

For example, shown in FIG. 1 is a schematic cross-sectional diagram illustrating a heat sink ball grid array in accordance with a prior art. Depicted in FIG. 1, there are multitudes of conductive solder balls 112 distributed on one side of a substrate 110. A die 114 is affixed to the other side of the substrate 110 and electrically connected the substrate 110 through some metal wires 116. A heat sink 118 covering the die 114 and metal wires 116 is configured for quickly dissipating the heat generated by the die 114 and protecting the metal wires 116 from deformation. Finally, the heat sink 118 is affixed and adhered to the substrate 110 with molding compound 120.

However, while the package structure aforementioned applies to the die manufactured by low k copper process, the combination of the heat sink 118 and molding compound 120 that has the coefficient of thermal expansion higher than the die 114 does would result in the increasing of internal stress. The increasing of internal stress causes the peeling problems among the layers in the die 114, the line layers in the substrate 110 or the die 114 and the substrate 110.

### SUMMARY OF THE INVENTION

Accordingly, a semiconductor package is provided to reduce the internal stress with the molding compound encapsulating the die.

Furthermore, with the position of the heat sink outside the package, a semiconductor package with a heat sink is provided to reduce the internal stress and dissipate the heat generated by the die.

Furthermore, a heat sink ball grid array package is provided with thermal interface material that both adheres the molding compound and heat sink and transfers the heat generated by the die.

A semiconductor package includes a die attached to a substrate. Multitudes of conductive structures, such as conductive wires or bumps, conductively connect the die and the substrate. One molding compound encapsulates the die, and thermal interface material is on the molding compound. Next, a heat sink is on the thermal interface material. The mold compound material performs a coefficient of thermal expansion smaller than the heat sink so as to prevent the die or substrate from the damages of internal stresses.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic cross-sectional diagram illustrating a heat sink ball grid array in accordance with a prior art.

FIG. 2 is a schematic cross-sectional diagram illustrating a heat sink ball grid array in accordance with the present invention.

FIG. 3 is a schematic cross-sectional diagram illustrating a package of flip chip in accordance with the present invention.

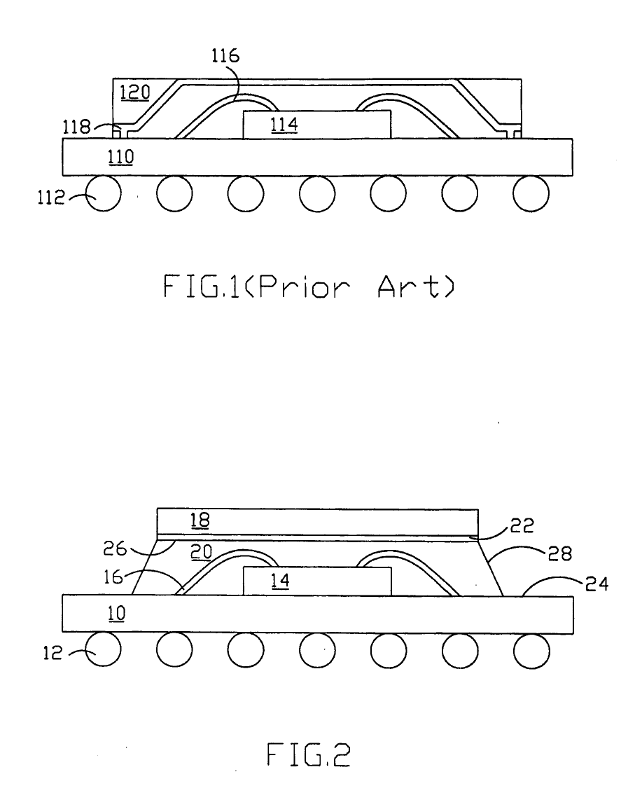

### DESCRIPTION OF THE PREFERRED EMBODIMENTS

Before describing the invention in detail, a brief discussion of some underlying concepts will first be provided to facilitate a complete understanding of the invention.

Shown in FIG. 2 is a schematic cross-sectional diagram illustrating a heat sink ball grid array in accordance with the present invention. Depicted in FIG. 2, there are multitudes of conductive solder balls 12 distributed on the underside of a substrate 10. The plate of a die 14 is affixed to the upside 24 of the substrate 10 and the other side thereof is electrically connected the upside 24 of the substrate 10 through some metal wires 16. A molding compound 20 covers the die 14 and the metal wires 16 and adheres to the upside 24 of the substrate 10. The molding compound 20 on the upside 24 has an upside surface 26 and a sidewall 28. Thermal interface material 22 covers on the upside surface 26 and a heat spreader 18 is thereon.

In one embodiment, the substrate 10, generally a substrate of ball grid array, such as multiple layer print circuit board, upholds the whole package and provides the signal connection. There are conductive pads (not shown in the figure) on the upside 24 for electric connection of the metal wires 16 to multitudes of conductive balls 12, such as solder balls, on the other side of the substrate 10 through some through holes.

Furthermore, the die 14 is manufactured by a low k copper process in the embodiment. One side of the die 14 is attached to the upside 24 of the substrate with an adhered film (not shown), the other side that is away from the substrate 10 has some conductive pads (not shown) for the electric connection of the metal wires 16 to the substrate 10. Next, in the embodiment, the metal wires 16, such as gold or aluminum wires, are implemented by any suitable wiring methods, such as adhesion of super sonic, thermal compressed adhesion, or stage method of thermal super sonic.

It is noted that the molding compound 20 directly encapsulates the die 14 and the metal wires 16 in a heat sink ball grid array. The molding compound 20 with some material characteristics thereof, such as epoxy resin or thermoset plastic, not only sealingly encompass the die 14 and the metal wires 16 but also adheres to the upside 24 of the substrate 10 around the die 14. Furthermore, the molding compound 20 also provides the metal wires 16 with buffer or necessary rigidity to prevent them from deformation by other force. In the embodiment, the molding compound 20 after formation may have a planar upside surface and a sidewall 28. It is noted that while the die 14 is manufactured by low K copper process, the molding compound 20 directly attaching the die 14 has a similar coefficient of thermal expansion (CTE) as the die 14. On the other hand, the molding compound 20 does not encapsulate a heat sink that has a larger coefficient of thermal expansion, so as to efficiently reduce both the residual internal stress in a package device and peelings in the substrate 10 or signal layer in the die 14.

In order to efficiently dissipate the heat generated by the die 14, a thermal interface material 22 is designed to form on the molding compound 20 and further dissipate the thermal-mechanical stress. In the embodiment, the thermal interface material 22 may seal tightly the molding compound 20, such as silicon gel, epoxies and phase change thermal interface materials or cured gel thermal interface material. Furthermore, in a preferred embodiment, the thermal interface material 22 is formed on the upside surface 26 of the molding compound 20, not limited, or covers over the whole surface of the molding compound 20, or depends on the shape or profile of the molding compound 20.

On the other hand, the heat sink 18 on the molding compound 22 still dissipates the heat generated by the die 14 through the molding compound 20 and the thermal interface material 22 of good thermal conductivity. In the embodiment, the heat sink 18 is made of rigid material that can seal tightly the thermal interface material 22 and has rigidity higher than the molding compound 20. In the embodiment, the heat sink 18 is made of rigid thermal conductive material, such as copper film or alloy, which protects the die 14 and the metal wires 16 from exterior force. It is noted that the design of the heat sink 18 is not limited to the shape shown in FIG. 2. The heat sink 18 in other shape, such as fan-shaped, or with a portion not sealing the thermal interface material 22 is also applied for the embodiment. It is noted that the heat sink 18 is designed to put the outside surface of one package structure so as to reduce the residual internal stress and prevent the die 14 or the substrate 10 from peelings.

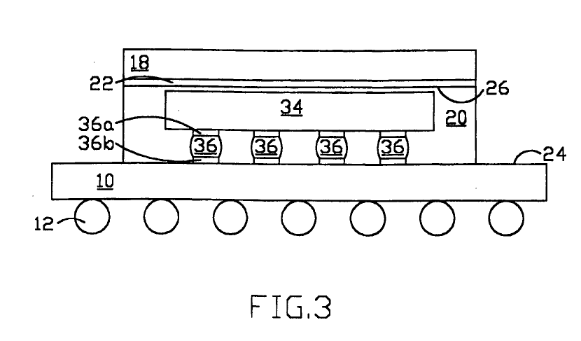

FIG. 3 is a schematic cross-sectional diagram illustrating a package of flip chip in accordance with the present invention. Similar as FIG. 2, there are multitudes of conductive solder balls 12 distributed on the underside of a substrate 10. Multitudes of conductive pads 36a and 36b are distributed on a flip chip 34 and the substrate 10, respectively. The flip chip 34 is affixed to the upside 24 of the substrate 10 through some conductive balls 36 mounting between each conductive pad 36a and each conductive pad 36b. A molding compound 20 encapsulates the flip chip 34 and the conductive balls 36 and adheres to the upside 24 of the substrate 10. The molding compound 20 on the upside 24 has an upside surface 26. The thermal interface material 22 covers on the upside surface 26 and a heat spreader 18 is thereon.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

1. A semiconductor package structure, comprising:
a substrate;
a die attached to said substrate;
a plurality of conductive wires electrically connected to said substrate and said die;
a molding compound encapsulating said die;
a thermal interface material above said molding compound; and
a heat sink on said thermal interface material.

2. The semiconductor package structure according to claim 1, wherein said die is manufactured by a low k copper process.

3. The semiconductor package structure according to claim 1, further comprising a plurality of conductive pads on said die for connecting said conductive wires.

4. The semiconductor package structure according to claim 1, further comprising a plurality of conductive pads on said substrate for connecting said conductive wires.

5. The semiconductor package structure according to claim 1, wherein said molding compound further encapsulates said conductive wires.

6. The semiconductor package structure according to claim 1, wherein said substrate has a plurality of conductive balls on an underside of said substrate.

7. The semiconductor package structure according to claim 6, further comprising said die attached to an upside of said substrate.

8. The semiconductor package structure according to claim 1, wherein said substrate has a signal layer.

9. A semiconductor package structure, comprising:
a substrate having a first surface;
a die having a second and a third surfaces, wherein said second surface is attached to said first surface;
a plurality of conductive wires electrically connected to said first and said third surfaces;
a molding compound encapsulating said die and said conductive wires, wherein said molding compound has a fourth surface;
a thermal interface material above said fourth surface; and
a heat sink on said thermal interface material, wherein said heat sink has a coefficient of thermal expansion bigger than said molding compound.

10. The semiconductor package structure according to claim 9, wherein said heat sink has rigidity bigger than said molding compound.

11. A semiconductor package structure, comprising:
a substrate;
a flip chip attached to said substrate;
a plurality of conductive balls attached and electrically connected to said substrate and said flip chip;
a molding compound encapsulating said flip chip and said conductive balls;
a thermal interface material above said molding compound; and
a heat sink on said thermal interface material.

12. The semiconductor package structure according to claim 11, further comprising a plurality of conductive pads respectively on said substrate and said flip chip for connecting said conductive balls.

13. The semiconductor package structure according to claim 11, wherein said substrate has a plurality of solder balls on an underside of said substrate.

14. The semiconductor package structure according to claim 11, wherein said substrate has a signal layer.
